(19) United States
(12) Patent Application Publication
(10) Pub. No.: US 2026/0367539 A1
(43) Pub. Date: Nov. 19, 2026

(54) AIRFLOW ADJUST SYSTEM FOR WORKPIECE TOOL AND METHOD OF OPERATING THE SAME

(71) Applicant: Taiwan Semiconductor Manufacturing Co., Ltd., Hsinchu (TW)

(72) Inventors: Yu Kai CHEN, Hsinchu (TW); Yang Lun HUANG, Hsinchu (TW); Yan Lin HUANG, Hsinchu (TW)

(73) Assignee: Taiwan Semiconductor Manufacturing Co., Ltd., Hsinchu (TW)

(21) Appl. No.: 19/755,158

(22) Filed: Jul. 27, 2026

Related U.S. Application Data
(63) Continuation of application No. 18/797,233, filed on Aug. 7, 2024.

(51) Int. Cl. G03F 7/00

(52) U.S. Cl. CPC G03F 7/70933; G03F 7/7085

(57) ABSTRACT

A workpiece processing tool includes at least a first processing region to perform a first process and second processing region to perform a second process. A first airflow assembly is within the first processing region and a second airflow assembly is within the second processing region. A source of air that is in fluid communication with a plurality of airflow dampers. A plurality of fluid passageways in fluid communication with the plurality of airflow dampers. The plurality of fluid passageways includes at least one first fluid passageway in fluid communication with the first airflow assembly, and at least one second fluid passageway in fluid communication with the second airflow assembly. A plurality of first particle sensors in the first processing region and a plurality of second particle sensors in the second processing region to detect respective levels of particles or pollutants within the first and second processing regions.

### PRIORITY CLAIM

This application is a continuation of U.S. patent application Ser. No. 18/797,233, filed on Aug. 7, 2024, which is incorporated by reference herein in its entirety.

### BACKGROUND

Semiconductor die or semiconductor packages are manufactured by utilizing various manufacturing steps, techniques, processes, or methods, as well as by utilizing various workpiece processing tools within a semiconductor manufacturing plant to conduct these manufacturing steps, techniques, processes, and methods. As workpieces pass through and are refined by the workpiece processing tools, particles or pollutants may build up within the workpiece processing tools over time as more and more of the workpieces are refined and processed by the workpiece processing tools. Eventually, the workpiece processing tools are cleaned, resulting in downtime of the workpiece processing tools to perform this cleaning process. For example, the workpieces generally are wafers that are refined by the workpiece processing tools within the semiconductor manufacturing plant to manufacture the semiconductor die or semiconductor packages. For example, the workpiece processing tools may include tools that are configured to, in operation, perform a lithography (e.g., photoresist lithography) step, a sputtering step, a thin film formation step, or some other suitable technique, process, or step to be performed within the semiconductor manufacturing plant when manufacturing the semiconductor die or semiconductor packages. At least some of these workpiece processing tools may include multiple distinct processing chambers for performing one or more steps of a manufacturing step, technique, process, or method.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a perspective view of a workpiece processing tool.

FIG. 1B is a schematic block diagram of a process block of the workpiece processing tool as shown in FIG. 1A.

FIG. 1C is one or more front views of one or more airflow systems or assemblies within the workpiece processing tool as shown in FIG. 1A.

FIG. 2A is a schematic block diagram of a work piece processing tool with one or more airflow systems or assemblies, in accordance with some embodiments.

FIG. 2B is a schematic view of the one or more airflow systems or assemblies and the one or more particle sensors within the workpiece processing tool as shown in FIG. 2A, in accordance with some embodiments.

FIG. 2C is one or more front views of one or more airflow systems or assemblies within the workpiece processing tool as shown in FIG. 2A.

FIG. 3 is a flowchart of a method of operating the one or more air systems of the process block as shown in FIG. 2A, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is directed to one or more embodiments of a workpiece processing tool including a process block that includes one or more processing regions that each carry out a step of a process to be performed within the process block of the workpiece processing tool. In at least one embodiment of the present disclosure, the one or more processing regions includes a first region, a second region, and a third region, and, in each of these respective regions, respective steps are performed to process one or more workpieces within the processing block of the workpiece processing tool. A first airflow system or assembly is within the first region, a second airflow system or assembly is within the second region, and a third airflow system or assembly is within the third region. The first, second, and third airflow systems or assemblies are configured to, in operation, control airflow passing through the first, second, and third regions, respectively, and the airflow passing through the first, second, and third regions is directed in an airflow direction that is directed away from a top end and towards a bottom end of the workpiece processing tool. A first plurality of particle or pollutant sensors are within the first region, a second plurality of particle or pollutant sensor are within the second region, and a third plurality of particle or pollutant sensors are within the third region. A first fan is within the first region, a second fan is within the second region, and the third fan is within the third region, and the first, second, and third fans are in close proximity to a bottom end of the workpiece processing tool. A processor is in electrical communication with the first, second, and third pluralities of particles or pollutant sensors, the processor is in electrical communication with a plurality of airflow dampers that are in fluid communication with a source of air, and the processor is in electrical communication with the first, second, and third fans. The airflow dampers are in fluid communication with the first, second, and third airflow systems or assemblies through a plurality of fluid passageways. The processor collects data and processes the data from the plurality of particle of pollutant sensors and then controls the airflow dampers and the first, second, and third fans in response to the processed data. For example, if the processor determines that an amount or level of the particles or pollutants are above a threshold level, the processor provides a control signal resulting in power being provided to at least one of, all of, or a combination of the first, second, and third fans in order to facilitate removing the particles or pollutants from the workpiece processing tool, and the processor provides a control signal to move at least one of, all of, or a combination of the plurality of dampers towards an opened position to increase airflow through the fluid passageways and successively increasing airflow through the first, second, and third airflow systems or assemblies, respectively. Alternatively, if the processor determines that the amount or level of the particles or pollutants are below a threshold level, the processor provides a control signal resulting in reducing or preventing power from being provided to at least one of, all of, or a combination of the first, second, and third fans in order to facilitate power saving, and the processor provides a control signal to move at least one of, all of, or a combination of the plurality of dampers towards a closed position to decrease airflow through the fluid passageways and successively decreasing airflow through the first, second, and third airflow systems or assemblies, respectively.

As will become readily apparent in view of the discussion that follows herein, the one or more embodiments of the workpiece processing tool has improved power efficiency in saving power by reducing power or preventing power being provided to the first, second, and third fans when the particle or pollutant level is less than the threshold level. As will become readily apparent in view of the discussion that follows herein, the one or more embodiments of the workpiece processing tool provides a reduced likelihood or prevents particles or pollutants from building up within the workpiece processing tool, reducing the likelihood of or preventing defects occurring within or on one or more workpieces being processed by the workpiece processing tool. As will become readily apparent in view of the discussion that follows herein, the one or more embodiments of the workpieces processing tool increases a period of time between cleaning operations of the workpiece processing tool, increasing running time of the workpiece processing tool and increasing a yield number of product (e.g., semiconductor die, packages, or some other similar or like type of product) manufactured and output by the FAB (semiconductor manufacturing plant).

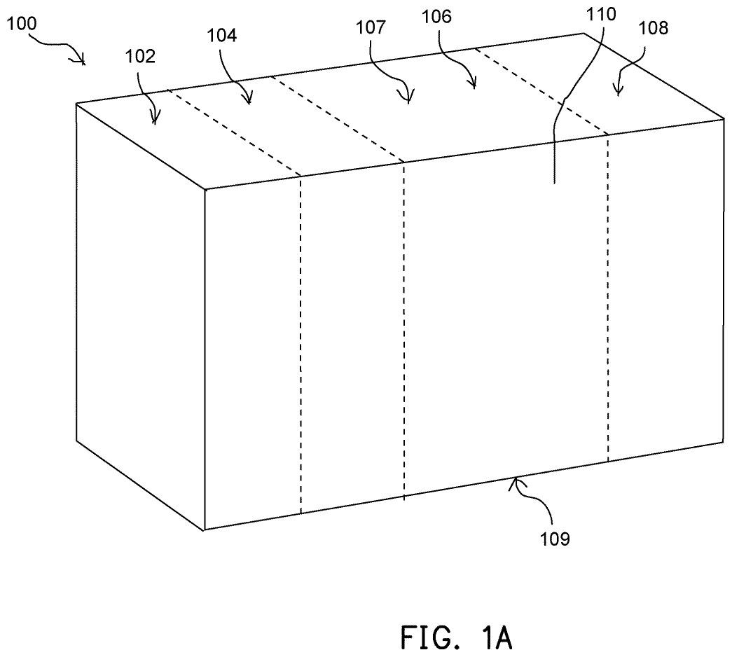

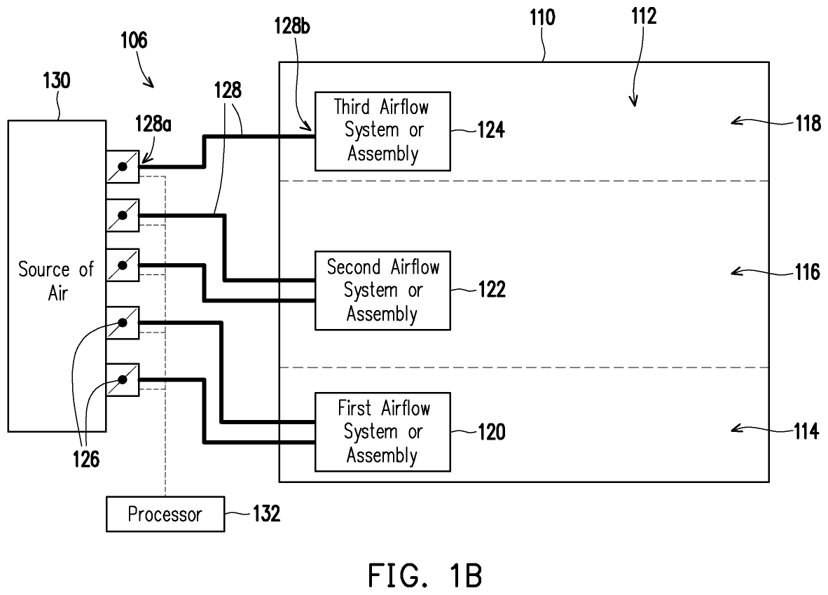

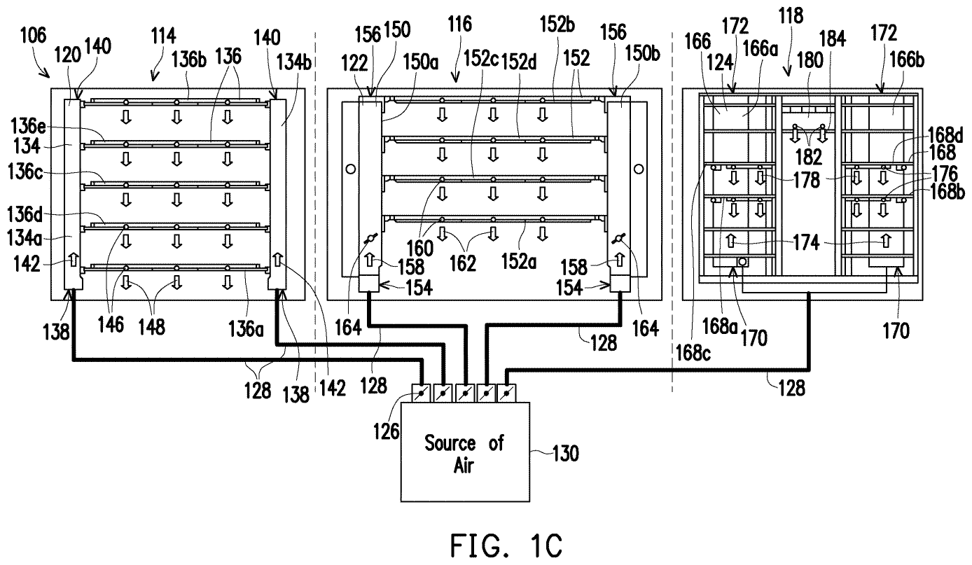

FIG. 1A is a perspective view of a workpiece processing tool 100. The workpiece processing tool 100 includes a carrier station base 102, a multipurpose block 104, a process block 106, and an interface block sub 108.

The carrier station base 102 is configured to, in operation, receive one or more carriers (e.g., workpiece cassettes) to insert one or more workpieces (e.g., wafers) transported to the workpiece processing tool within the one or more carriers. The one or more carriers (not shown) may be picked up and transported to the workpiece processing tool 100 by an overhead transport system within a FAB (semiconductor manufacturing plant) in which the workpiece processing tool 100 is present.

The multipurpose block 104 is configured to, in operation, store one or more workpieces to be processed by the process block 106. For example, the multipurpose block 104 may include a rack on which the one or more workpieces are temporarily stored until the process block 106 is ready to receive the one or more workpieces to process the one or more workpieces.

The process block 106 is configured to, in operation, perform one or more steps of a process to refine and process the one or more workpieces within one or more processing chambers of the process block 106. For example, when the workpiece processing tool 100 is a photolithography tool, the process block may contain multiple processing chambers and a respective step of one or more steps of the photolithography process is performed in each respective processing chamber of the one or more processing chambers.

The interface block sub 108 is configured to, in operation, transfer a wafer through the interface block sub 108 to a scanner, which in at least some situations is within the workpiece processing tool 100. In at least one alternative situation, the scanner is external to the tool 100. The scanner is configured to, in operation, scan the one or more workpieces to detect any defects that are present on and within the one or more workpieces after going through the process within the process block 106.

The workpiece processing tool 100 includes a first end 107 and a second end 109. Based on the orientation of the workpiece processing tool 100 as shown in FIG. 1A, the first end 107 is a top end of the workpiece processing tool 100 and the second end 109 is a bottom end of the workpiece processing tool 100.

FIG. 1B is a schematic block diagram of the process block 106 of the workpiece processing tool 100 as shown in FIG. 1A. The process block 106 includes a housing 110 that delimits or defines at least one processing chamber 112.

The process block 106 includes a first region 114, a second region 116, and a third region 118. In some situations, the first, second, and third regions 114, 116, 118 of the process block 106 may be separated and distinct by chamber walls resulting in the at least one processing chamber 112 being broken up into multiple processing chambers. For example, when the first, second, and third regions 114, 116, 118 are delimited from each other by these respective chamber walls, the first region 114 is a first chamber, the second region 116 is a second chamber, and the third region 118 is a third chamber.

When the workpiece processing tool 100 is a photolithography tool, the first region 114 is a region of the process block 106 of the workpiece processing tool 100 in which one or more workpieces are positioned within and are coated with a photoresist material (e.g., a hard mask). After the photoresist material has been formed on respective surfaces of the one or more workpieces within the first region, the one or more workpieces are transported to the second region 116. Once the one or more workpieces, which are now coated with the photoresist material, are within the second region 116, the photoresist material is exposed to an ultraviolet (UV) light. Before reaching the photoresist material, the UV light may pass through a stencil to only expose the photoresist material to UV light at selected locations. After the photoresist material has been exposed to the UV light, the photoresist material is exposed to a first photoresist etchant chemical (e.g., a solvent) that patterns the photoresist material generating one or more openings within the photoresist material. Once the one or more openings are formed in the photoresist material such that the photoresist material is patterned, the photoresist material is heated up by a hot plate structure curing and hardening the photoresist material. After curing the resist material, a conductive or metal layer partially covered by the patterned photoresist material is exposed to an etchant chemical that etches away respective portions of the conductive or metal layer exposed by the one or more openings resulting in the conductive or metal layer being patterned. After the metal layer has been patterned by being exposed to the etchant chemical through the one or more openings in the photoresist material, the patterned photoresist material is removed from the patterned metal layer by exposing the photoresist material to a second photoresist etchant material. After the patterned photoresist material has been removed from the metal layer, the one or more workpieces may then be further processed within the second region 116 of the process block 106 or the one or more workpieces are then transferred to the third region 118. Once the one or more workpieces are in the third region 118, the one or more workpieces are transported to the scanner that is configured to, in operation, scan the one or more workpieces to detect any defects that are present on and within the one or more workpieces after going through the process within the process block 106. In other words, the third region 118 may be a temporary storage region in which the one or more workpieces are to be temporarily stored until being transported to the scanner.

A first airflow system or assembly 120 is within the first region 114, a second airflow system or assembly 122 is within the second region 116, and a third airflow system or assembly 124 is within the third region 118. The first, second, and third airflow systems or assemblies are present to increase or decrease airflow within the first, second, and third regions 114, 116, 118, respectively. The first, second, and third airflow systems and assemblies 120, 122, 124 are in fluid communication with one or more of airflow dampers 126 through one or more fluid passageways 128. The one or more fluid passageways 128 have first ends 128a that are each in fluid communication with a corresponding airflow damper of the plurality of airflow dampers 126, and the one or more fluid passageways 128 have second ends 128b that are each in fluid communication with a corresponding one of the first, second, and third airflow systems or assemblies 120, 122, 124.

The one or more airflow dampers 126 have a fully closed position and a fully opened position. When a respective airflow damper of the one or more airflow dampers 126 is in the fully closed position, the respective airflow damper prevents air from reaching the corresponding one of the first, second, and third airflow systems or assemblies 120, 122, 124, respectively. When the respective airflow damper of the one or more airflow dampers 126 is in the fully opened position, the respective airflow damper allows for as much air as possible to the corresponding one of the first, second, and third airflow systems or assemblies 120, 122, 124, respectively.

The one or more airflow dampers 126 are in fluid communication with a source of air 130, and the one or more airflow dampers 126 are between the first ends 128a of the one or more fluid passageways 128 and the source of air 130. The one or more airflow dampers 126 are configured to, in operation, control an amount of air that travels from the source of air 130 into the one or more fluid passageways 128 and, ultimately, to the first, second, and third airflow systems or assemblies 120, 122, 124, respectively. The one or more airflow dampers 126 are in electrical communication with a processor 132, and the processor 132 is configured to, in operation, control the one or more airflow dampers 126 to provide air from the source of air 130 to the first, second, and third airflow systems and assemblies 120, 122, 124 through the one or more fluid passageways 128. The one or more airflow dampers 126 may be controlled individually by the processor 132 to open and close each of the airflow dampers 126 by various amounts to provide selected or determined amounts of air from the source of air 130 to the first, second, and third airflow systems or assemblies 120, 122, 124 through the one or more fluid passageways 128 to increase or decrease airflow through the first, second, and third airflow systems or assemblies 120, 122, 124 and into the first, second, and third regions 114, 116, 118 of the process block 106.

When the process block is being utilized (e.g., in operation) to process the one or more workpieces, particles and pollutants build up over time through the first region 114, the second region 116, and the third region 118. As these particles and pollutants build up, the likelihood of defects being generated on or within the one or more workpieces when being processed or refined by the process block is increased as compared to when the process block is clean and void of these particles and pollutants. To remove these particles and pollutants that build up over time within the process block 106, a cleaning operation is performed on the process block 106 and the workpiece processing tool 100 after a selected period of time. However, when the cleaning operation is being performed on the process block 106 and the workpiece processing tool 100, the workpiece processing tool 100 is offline such that the workpiece processing tool 100 cannot be utilized to process and refine the one or more workpieces. This downtime of the workpiece processing tool 100 to perform this cleaning operation results in limiting a yield number of semiconductor die or packages being manufactured. Furthermore, as the first, second, and third airflow systems or assemblies 120, 122, 124 are generally provided with a continuous fixed volume of air from the source of air 130 through the one or more airflow dampers 126 and the one or more fluid passageways 128, the workpiece processing tool 100 takes a relatively large amount of power to run such that operating costs of the workpiece processing tool 100 are relatively high. In view of this above discussion with respect to the workpiece processing tool 100, the present disclosure is directed to providing one or more embodiments of a workpiece processing tool that allows for the particles or pollutants to be expelled from a process block and has better power efficiency relative to the workpiece processing tool 100.

FIG. 1C is one or more front views of the one or more (i.e., first, second, and third) airflow systems or assemblies 120, 122, 124 of the process block 106. As discussed earlier herein, the first, second, and third airflow systems or assemblies 120, 122, 124 are within different regions (e.g., the first region 114, the second region 116, and the third region 118, respectively).

As shown in the left-hand most image in FIG. 1C, the first air flow system or assembly 120 includes one or more vertical airflow structures 134 and one or more horizontal airflow structures 136 that are transverse, perpendicular, orthogonal, or at a non-zero angle to the one or more vertical airflow structures 134. The one or more vertical airflow structures 134 are in fluid communication with the one or more horizontal airflow structures 136. As shown in FIG. 1C, in this embodiment of the process block 106, the one or more vertical airflow structures 134 includes a pair of vertical airflow structures 134a, 134b having a first vertical airflow structure 134a and a second vertical airflow structure 134b that are spaced apart from each other and opposite to each other about the one or more horizontal airflow structures 136. As shown in FIG. 1C, in this embodiment of the process block 106, the one or more horizontal airflow structures 136 includes a plurality of horizontal airflow structures 136. In this embodiment of the process block 106, the plurality of horizontal airflow structures 136 includes five horizontal airflow structures 136 (i.e., first, second, third, fourth, and fifth horizontal airflow structures). The five horizontal airflow structures 136 include a lowermost horizontal airflow structure 136a (i.e., a first horizontal airflow structure 136a) in closer proximity to the second end 109 (i.e., the bottom end) of the workpiece processing tool 100 than the first end 107 (i.e., the top end) of the workpiece processing tool 100. The five horizontal airflow structures 136 include an uppermost horizontal airflow structure 136b (i.e., a second horizontal airflow structure 136b) in closer proximity to the first end 107 (i.e., the top end) of the workpiece processing tool 100 than the second end 109 (i.e., the bottom end) of the workpiece processing tool 100. The five horizontal airflow structures 136 include three intermediate horizontal airflow structures 136c, 136d, 136e that are between the lowermost first horizonal airflow structures 136a and the uppermost horizontal airflow structures 136b.

The first and second vertical airflow structures 134a, 134b have lower ends 138 and upper ends 140. The lower ends 138 are in closer proximity to the second end 109 of the workpiece processing tool 100 than the first end 107 of the workpiece processing tool 100, and the upper ends 140 are in closer proximity to the first end 107 of the workpiece processing tool 100 than the second end 109 of the workpiece processing tool 100. The lower ends 138 of the first and second vertical airflow structures 134a, 134b are in fluid communication with respective airflow dampers of the one or more airflow dampers 126 through respective fluid passageways 128 of the one or more fluid passageways 128. Air passes along the respective fluid passageways 128 to the lower ends 138 of the first and second vertical airflow structures 134a, 134b. The air continues upward and along the first and second vertical airflow structures 134a, 134b as represented by the arrows 142 towards upper ends 140 of the first and second vertical airflow structures 134a, 134b. The first and second vertical airflow structures 134a, 134b are in fluid communication with the five horizontal airflow structures 136a, 136b, 136c, 136d, 136e. As the air moves upward and along the first and second vertical airflow structures 134a, 134b, the air passes into the five horizontal airflow structures 136a, 136b, 136c, 136d, 136e and into the first region 114 of the process block 106. As the air is ejected or expelled from the five horizontal airflow structures 136a, 136b, 136c, 136d, 136e through one or more airflow openings, holes, or outlets 146 in each of the five horizontal airflow structures 136a, 136b, 136c, 136d, 136e, the air is directed in an airflow direction as represented by the arrows 148. The one or more airflow openings 146 are directed downwards such that the airflow direction as represented by the arrows 148 is directed away from the first end 107 of the workpiece processing tool 100 towards the second end 109 of the workpiece processing tool 100. In other words, the airflow direction represented by the arrows 162 is directed in a downward direction.

As shown in the middle or center image in FIG. 1C, the second air flow system or assembly 122 includes one or more vertical airflow structures 150 and one or more horizontal airflow structures 152 that are transverse, perpendicular, orthogonal, or at a non-zero angle to the one or more vertical airflow structures 150. The one or more vertical airflow structures 150 are in fluid communication with the one or more horizontal airflow structures 152. As shown in FIG. 1C, in this embodiment of the process block 106, the one or more vertical airflow structures 150 includes a pair of vertical airflow structures 150a, 150b having a first vertical airflow structure 150a and a second vertical airflow structure 150b that are spaced apart from each other and opposite to each other about the one or more horizontal airflow structures 152. As shown in FIG. 1C, in this embodiment of the process block 106, the one or more horizontal airflow structures 152 includes a plurality of horizontal airflow structures 152. In this embodiment of the process block 106, the plurality of horizontal airflow structures 152 includes four horizontal airflow structures 152 (i.e., first, second, third, and fourth horizontal airflow structures). The four horizontal airflow structures 152 include a lowermost horizontal airflow structure 152a (i.e., a first horizontal airflow structure 152a) in closer proximity to the second end 109 (i.e., the bottom end) of the workpiece processing tool 100 than the first end 107 (i.e., the top end) of the workpiece processing tool 100. The four horizontal airflow structures 152 include an uppermost horizontal airflow structure 152b (i.e., a second horizontal airflow structure 136b) in closer proximity to the first end 107 (i.e., the top end) of the workpiece processing tool 100 than the second end 109 (i.e., the bottom end) of the workpiece processing tool 100. The four horizontal airflow structures 152 include two intermediate horizontal airflow structures 152c, 152d that are between the lowermost horizonal airflow structure 152a and the uppermost horizontal airflow structures 152b.

The first and second vertical airflow structures 150a, 150b have lower ends 154 and upper ends 156. The lower ends 154 are in closer proximity to the second end 109 of the workpiece processing tool 100 than the first end 107 of the workpiece processing tool 100, and the upper ends 156 are in closer proximity to the first end 107 of the workpiece processing tool 100 than the second end 109 of the workpiece processing tool 100. The lower ends 154 of the first and second vertical airflow structures 150a, 150b are in fluid communication with respective airflow dampers of the one or more airflow dampers 126 through respective fluid passageways 128 of the one or more fluid passageways 128. Air passes along the respective fluid passageways 128 to the lower ends 154 of the first and second vertical airflow structures 150a, 150b. The air continues upward and along the first and second vertical airflow structures 150a, 150b as represented by the arrows 158 towards upper ends 156 of the first and second vertical airflow structures 150a, 150b. The first and second vertical airflow structures 150a, 150b are in fluid communication with the four horizontal airflow structures 152a, 152b, 152c, 152d. As the air moves upward and along the first and second vertical airflow structures 150a, 150b, the air passes into the four horizontal airflow structures 152a, 152b, 152c, 152d and into the second region 116 of the process block 106. As the air is ejected or expelled from the four horizontal airflow structures 152a, 152b, 152c, 152d through one or more airflow openings, holes, or outlets 160 in each of the four horizontal airflow structures 152a, 152b, 152c, 152d, the air is directed in an airflow direction as represented by the arrows 162. The one or more airflow openings 160 are directed downwards such that the airflow direction as represented by the arrows 162 is directed away from the first end 107 of the workpiece processing tool 100 towards the second end 109 of the workpiece processing tool 100. In other words, the airflow direction represented by the arrows 162 is directed in a downward direction.

In this embodiment, one or more airflow control structures 164 are present within the first and second vertical airflow structures 150a, 150b. The one or more airflow control structures 164 may be configured to, in operation, further control the airflow passing into and through the first and second vertical airflow structures 150a, 150b, respectively.

As shown in the right-hand most image in FIG. 1C, the third air flow system or assembly 124 includes one or more vertical airflow structures 166 and one or more horizontal airflow structures 168 that are transverse, perpendicular, orthogonal, or at a non-zero angle to the one or more vertical airflow structures 166. The one or more vertical airflow structures 166 are in fluid communication with the one or more horizontal airflow structures 168. As shown in FIG. 1C, in this embodiment of the process block 106, the one or more vertical airflow structures 166 includes a pair of vertical airflow structures 166a, 166b having a first vertical airflow structure 166a and a second vertical airflow structure 166b that are spaced apart from each other. As shown in FIG. 1C, in this embodiment of the process block 106, the one or more horizontal airflow structures 168 includes a plurality of horizontal airflow structures 168. In this embodiment of the process block 106, the plurality of horizontal airflow structures 168 includes four horizontal airflow structures 168a, 168b, 168c, 168d (i.e., first, second, third, and fourth horizontal airflow structures). The four horizontal airflow structures 168a, 168b, 168c, 168d include two lowermost horizontal airflow structures 168a, 168b (i.e., a first and second horizontal airflow structure 168a, 168b) in closer proximity to the second end 109 (i.e., the bottom end) of the workpiece processing tool 100 than the first end 107 (i.e., the top end) of the workpiece processing tool 100. The two lowermost horizontal airflow structures 168a, 168b are spaced apart from each other. The four horizontal airflow structures 168 include two uppermost horizontal airflow structures 168c, 168d (i.e., a third and fourth horizontal airflow structure 136b) in closer proximity to the first end 107 (i.e., the top end) of the workpiece processing tool 100 than the second end 109 (i.e., the bottom end) of the workpiece processing tool 100. The two uppermost airflow structures 168c, 168d are spaced apart from each other.

The first and second vertical airflow structures 166a, 166b have lower ends 170 and upper ends 172. The lower ends 170 are in closer proximity to the second end 109 of the workpiece processing tool 100 than the first end 107 of the workpiece processing tool 100, and the upper ends 172 are in closer proximity to the first end 107 of the workpiece processing tool 100 than the second end 109 of the workpiece processing tool 100. The lower ends 170 of the first and second vertical airflow structures 166a, 166b are in fluid communication with respective airflow dampers of the one or more airflow dampers 126 through a respective fluid passageway 128 of the one or more fluid passageways 128. Air passes along the respective fluid passageway 128 to the lower ends 170 of the first and second vertical airflow structures 166a, 166b. The air continues upward and along the first and second vertical airflow structures 166a, 166b as represented by the arrows 174 towards upper ends 156 of the first and second vertical airflow structures 166a, 166b. The first and second vertical airflow structures 166a, 166b are in fluid communication with the four horizontal airflow structures 168a, 168b, 168c, 168d. As the air moves upward and along the first and second vertical airflow structures 166a, 166b, the air passes into the four horizontal airflow structures 168a, 168b, 168c, 168d and into the third region 118 of the process block 106. As the air is ejected or expelled from the four horizontal airflow structures 168a, 168b, 168c, 168d through one or more airflow openings, holes, or outlets 176 in each of the four horizontal airflow structures 168a, 168b, 168c, 168d, the air is directed in an airflow direction as represented by the arrows 178. The one or more airflow openings 160 are directed downwards such that the airflow direction as represented by the arrows 178 is directed away from the first end 107 of the workpiece processing tool 100 towards the second end 109 of the workpiece processing tool 100. In other words, the airflow direction represented by the arrows 178 is directed in a downward direction.

In this embodiment, the third airflow system or assembly 124 includes an airflow head 180, which is in fluid communication with at least one of the one or more vertical airflow structures 166 or the one or more horizontal airflow structures 168. The airflow head 180 includes one or more airflow openings, holes, or outlets 182 that eject or expel air into the third region 118 in an airflow direction as represented by arrows 184.

The respective vertical airflow structures 134, 150, 166 along with the horizontal airflow structures 136, 152, 168 of the first, second, and third airflow assemblies or systems 120, 122, 124 define one or more airflow pathways through which air readily passes from the source of air and into the first, second, and third regions 114, 116, 118, respectively.

As set forth earlier herein, the first, second, and third airflow systems or assemblies 120, 122, 124 are generally provided with a continuous fixed volume of air from the source of air 130 through the one or more airflow dampers 126 and the one or more fluid passageways 128. The workpiece processing tool 100 takes a relatively large amount of power to run such that operating costs of the workpiece processing tool 100 are relatively high. In view of this above discussion with respect to the workpiece processing tool 100, the present disclosure is directed to providing one or more embodiments of a workpiece processing tool that allows for the particles or pollutants to be expelled from a process block and has better power efficiency relative to the workpiece processing tool 100.

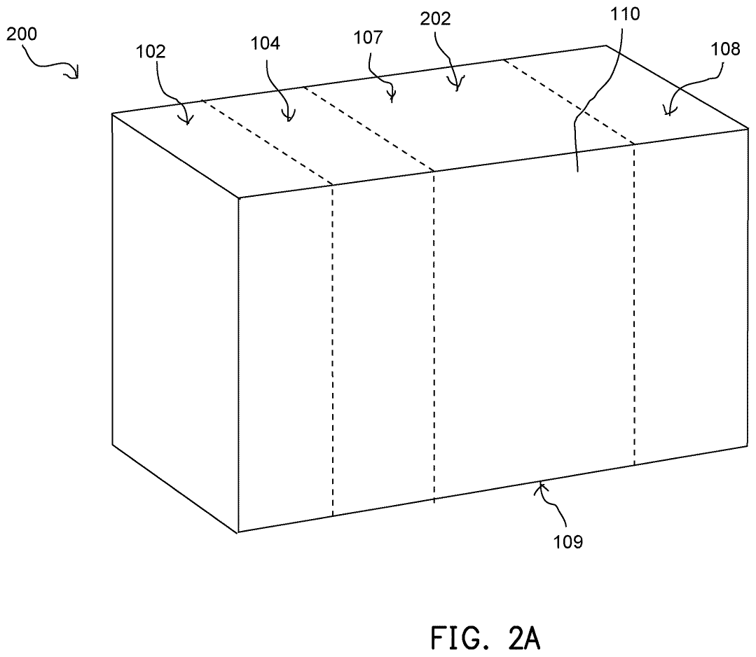

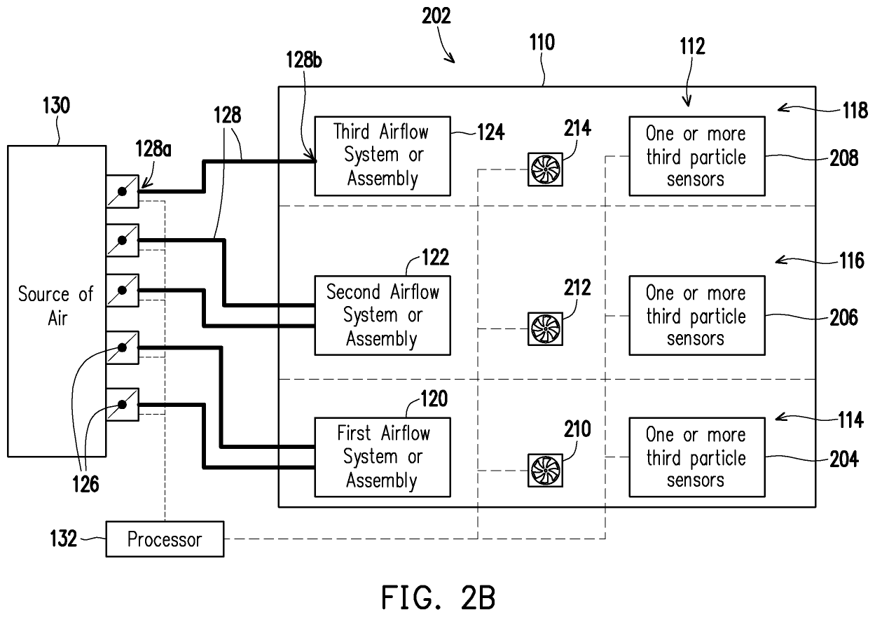

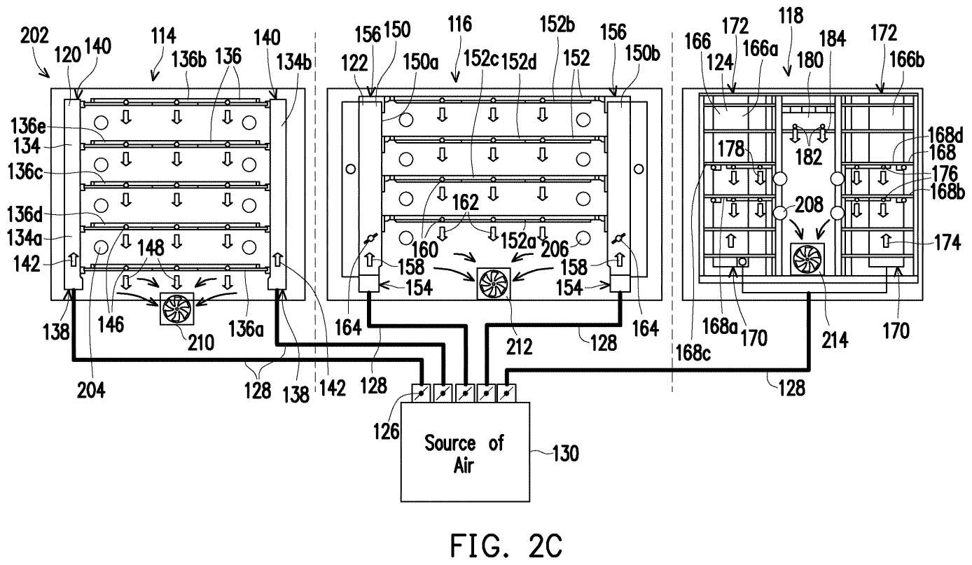

FIG. 2A is a perspective view of a workpiece processing tool 200, in accordance with some embodiments. The workpiece processing tool 200 is similar to the workpiece processing tool 100. Similar to the workpiece processing tool 100 as shown in FIG. 1A, the workpiece processing tool 200 as shown in FIG. 2A includes carrier station base 102, the multipurpose block 104, the interface block sub 108, and the process block 202, which is between the multipurpose block 104 and the interface block 108 like the process block 106 of the workpiece processing tool 100. The process block 202 is the same or similar to the process block 106. However, the process block 202 of the workpiece processing tool 200 includes or contains additional and different features that are not present within the process block 106 of the workpiece processing tool 100. The following discussion of the process block 202 of the workpiece processing tool 200 will focus on the additional and different features of the process block 202 relative to the process block. The same or similar features of the process block 106 and the process block 202 will be provided with the same or similar reference numerals. For the sake of simplicity and brevity of the present disclosure, details of these same or similar details between these same or similar features of the process block 106 and the process block 202 may not be reproduced here if already discussed in detail as set forth earlier herein with respect to describing the process block 106 as shown in FIGS. 1A-1C.

FIG. 2B is a schematic block diagram of a workpiece processing tool 200 with one or more airflow systems or assemblies, in accordance with some embodiments. Unlike the process block 106 of the workpiece processing tool 100, the process block 202 of the workpiece processing tool 200 includes one or more first particle or pollutant sensors 204, one or more second particle or pollutant sensors 206, and one or more third particle or pollutant sensors 208. Unlike the process block 106 of the workpiece processing tool 100, the process block 202 of the workpiece processing tool 200 includes a first fan 210, a second fan 212, and a third fan 214.

The one or more first particle sensors 204 are in the first region 114, the one or more second particle sensors 206 are in the second region 116, and the one or more third particle sensors 208 are in the third region 118. The one or more first particle sensors 204, the one or more second particle sensors 206, and the one or more third particle sensors 208 are configured to, in operation, measure a level of particles or pollutants within a corresponding region of the first, second, and third regions 114, 116, 118, respectively, in real time.

Similar to the process block 106, the processor 132 of the process block 202 is in electrical communication with one or more airflow dampers 126. However, unlike the process block 106, the processor 132 of the process block 202 is also in electrical communication with the one or more first particle sensors 204, the one or more second particle sensors 206, and the one or more third particle sensors 208, and the processor 132 of the process block 202 is also in electrical communication with the first fan 210, the second fan 212, and the third fan 214. The processor 132 is configured to receive signals from and send signals to these respective components to control airflow through the first region the process block 106. In some other embodiments, the process block 106 includes multiple ones of the processor 132 and the multiple ones of the processors 132 are in electrical communication with a control hub that is configured to, in operation, collect signals from and send signals to ones of the processors 132 to control the workpiece processing tool 200 and the process block 202 of the workpiece processing tool 200.

The one or more first particle sensors 204 measure a level of particles or pollutants within the first region 114. The one or more first particle sensors 204 send one or more signals to the processor 132, and the processor 132, which may be or may include a microprocessor, receives the one or more signals from the one or more first particle sensors 204 and processes those signals. If the processor 132 determines, based on processing the one or more signals from the one or more first particle sensors 204, that the level of particles or pollutants within the first region 114 is greater than a selected threshold, the processor 132 outputs a signal to the first fan 210 to activate the first fan 210 or to speed up the first fan 210 to further facilitate and increase the airflow through the first region 114. Similarly, if the processor 132 determines, based on processing the one or more signals from the one or more first particle sensors 204, that the level of particles or pollutants within the first region 114 is greater than a selected threshold, the processor 132 outputs a signal to at least one of the respective airflow dampers of the one or more airflow dampers 126 to further facilitate and increase the airflow through the first airflow system or assembly 120, increasing the airflow through the first region 114. In some situations, the processor 132 may send a signal to only one of the first airflow system or assembly 120 or the first fan 210 to increase the airflow within the first region 114, or, in some situations, the processor 132 may send signals to both the first airflow system or assembly 120 and the first fan 210 to increase the airflow within the first region 114. By increasing the airflow within the first region 114, the excess particles or pollutants are more rapidly and efficiently expelled from the first region 114, bringing the level of the particles and pollutants within the first region 114 below the selected threshold.

Once the level of particles or pollutants within the first region 114 is below the selected threshold, the processor 132 outputs a signal to the first fan 210 to slow down or deactivate the first fan 210 to conserve energy. Once the level of particles or pollutants within the first region 114 is below the selected threshold, the processor 132 outputs at least one signal to at least one airflow damper of the one or more airflow dampers 126 to reduce the airflow through the first airflow system or assembly 120. In some situations, the processor 132 sends a signal to only one of the first fan 210 or to the at least one airflow damper of the one or more airflow dampers 126.

The one or more second particle sensors 206 measure a level of particles or pollutants within the second region 116. The one or more second particle sensors 206 send one or more signals to the processor 132, and the processor 132, which may be or may include a microprocessor, receives the one or more signals from the one or more second particle sensors 206 and processes those signals. If the processor 132 determines, based on processing the one or more signals from the one or more second particle sensors 206, that the level of particles or pollutants within the second region 116 is greater than a selected threshold, the processor 132 outputs a signal to the second fan 212 to activate the second fan 212 or to speed up the second fan 212 to further facilitate and increase the airflow through the second region 116. Similarly, if the processor 132 determines, based on processing the one or more signals from the one or more second particle sensors 206, that the level of particles or pollutants within the second region 116 is greater than a selected threshold, the processor 132 outputs a signal to at least one of the respective airflow dampers of the one or more airflow dampers 126 to further facilitate and increase the airflow through the second airflow system or assembly 122, increasing the airflow through the second region 116. In some situations, the processor 132 may send a signal to only one of the second airflow system or assembly 122 or the second fan 212 to increase the airflow within the second region 116, or, in some situations, the processor 132 may send signals to both the second airflow system or assembly 122 and the second fan 212 to increase the airflow within the second region 116. By increasing the airflow within the first region 114, the excess particles or pollutants are more rapidly and efficiently expelled from the first region, bringing the level of the particles and pollutants within the first region below the selected threshold. By increasing the airflow within the second region 116, the excess particles or pollutants are more rapidly and efficiently expelled from the second region 116, bringing the level of the particles and pollutants within the second region 116 below the selected threshold.

Once the level of particles or pollutants within the second region 116 is below the selected threshold, the processor 132 outputs a signal to the second fan 212 to slow down or deactivate the second fan 212 to conserve energy. Once the level of particles or pollutants within the second region 116 is below the selected threshold, the processor 132 outputs at least one signal to at least one airflow damper of the one or more airflow dampers 126 to reduce the airflow through the second airflow system or assembly 122. In some situations, the processor 132 sends a signal to only one of the second fan 212 or to the at least one airflow damper of the one or more airflow dampers 126.

The one or more third particle sensors 208 measure a level of particles or pollutants within the third region 118. The one or more third particle sensors 208 send one or more signals to the processor 132, and the processor 132, which may be or may include a microprocessor, receives the one or more signals from the one or more third particle sensors 208 and processes those signals. If the processor 132 determines, based on processing the one or more signals from the one or more third particle sensors 208, that the level of particles or pollutants within the third region 118 is greater than a selected threshold, the processor 132 outputs a signal to the third fan 214 to activate the third fan 214 or to speed up the third fan 214 to further facilitate and increase the airflow through the third region 118. Similarly, if the processor 132 determines, based on processing the one or more signals from the one or more third particle sensors 208, that the level of particles or pollutants within the third region 118 is greater than a selected threshold, the processor 132 outputs a signal to at least one of the respective airflow dampers of the one or more airflow dampers 126 to further facilitate and increase the airflow through the third airflow system or assembly 124, increasing the airflow through the third region 118. In some situations, the processor 132 may send a signal to only one of the third airflow system or assembly 124 or the third fan 214 to increase the airflow within the third region 118, or, in some situations, the processor 132 may send signals to both the third airflow system or assembly 124 and the third fan 214 to increase the airflow within the third region 118. By increasing the airflow within the third region 118, the excess particles or pollutants are more rapidly and efficiently expelled from the third region 118, bringing the level of the particles and pollutants within the third region 118 below the selected threshold.

Once the level of particles or pollutants within the third region 118 is below the selected threshold, the processor 132 outputs a signal to the third fan 214 to slow down or deactivate the third fan 214 to conserve energy. Once the level of particles or pollutants within the second region 116 is below the selected threshold, the processor 132 outputs at least one signal to at least one airflow damper of the one or more airflow dampers 126 to reduce the airflow through the third airflow system or assembly 124. In some situations, the processor 132 sends a signal to only one of the third fan 214 or to the at least one airflow damper of the one or more airflow dampers 126.

FIG. 2B is a schematic view of the first, second, and third airflow systems or assemblies 120, 122, 124 and the one or more first, second, and third particle sensors 204, 206, 208 within the process block 202 of the workpiece processing tool 200 as shown in FIG. 2A, in accordance with some embodiments. As process block 202 of the workpiece processing tool 200 includes several of the same or similar features as the process block 106 of the workpiece processing tool 100, these same or similar features between the process block 202 of the workpiece processing tool 200 and the process block 106 of the workpiece processing tool 100 are provided with the same or similar reference numerals in the workpiece processing tool as shown in FIG. 2B. However, unlike the process block 106, the process block 202 contains additional and different features, and, therefore, the following discussion will focus on these additional and different features. For the sake of simplicity and brevity of the present disclosure, the details of the same or similar features between the process block 202 and the process block 106 may not be reproduced herein.

The one or more first particle sensors 204 is a plurality of first particle sensors 204 that are within the first region 114. There are two of the first particle sensors 204 between adjacent pairs of the one or more horizontal airflow structures 136. As discussed earlier herein, the one or more first particle sensors 204 measure the level of particles or pollutants within the first region 114. As there are two of the first particle sensors 204 between each adjacent pair of the horizontal airflow structures 136, there are a total of ten of the one or more first particle sensors 204. In an alternative embodiment, there may be a different number of the one or more first particle sensors 204 between each adjacent pair of the one or more horizontal airflow structures 136 such that there are more than ten or less than ten of the one or more first particle sensors 204. In an alternative embodiment, there may be at least one additional first particle sensor 204 below the lowest horizontal airflow structure 136 such that there are twelve of the one or more first particle sensors 204. In other words, the number and placement of the one or more first particle sensors 204 may be adapted or changed depending on the process that the process block 202 of the workpiece processing tool 200 is to perform.

The one or more second particle sensors 206 is a plurality of second particle sensors 206 that are within the second region 116. There are two of the second particle sensors 206 between adjacent pairs of the one or more horizontal airflow structures 152, and there are two second particle sensors 206 below the lowest horizontal airflow structure 152a. As discussed earlier herein, the one or more second particle sensors 206 measure the level of particles or pollutants within the second region 116. As there are two of the second particle sensors 206 between each adjacent pair of the horizontal airflow structures 152 and two below the lowest horizontal airflow structure 152a, there are a total of eight of the one or more second particle sensors 206. In an alternative embodiment, there may be none of the one or more second particle sensors below the lowest horizontal airflow structure 152a such that there is a total of six of the one or more second particle sensors 206. In other words, the number and placement of the one or more second particle sensors 206 may be adapted or changed depending on the process that the process block 202 of the workpiece processing tool 200 is to perform.

The one or more third particle sensors 208 is a plurality of third particle sensors 208 that are within the third region 118. There are two of the one or more third particle sensors 208 laterally adjacent to the two uppermost horizontal airflow structures 168c, 168d and there are two of the one or more third particle sensors 208 laterally adjacent to the two lowermost horizontal airflow structures 168a, 168b. As discussed earlier herein, the one or more third particle sensors 208 measure the level of particles or pollutants within the third region 118. As there are two of the one or more third particle sensors 208 laterally adjacent to the uppermost horizontal airflow structures 168c, 168d and two of the one or more third particle sensors 208 are laterally adjacent to the two lowermost horizontal airflow structures 168a, 168b, there is a total of four of the one or more third particle sensors 208. In an alternative embodiment, the number and placement of the one or more third particle sensors 208 may be adapted or changed depending on the process that the process block 202 of the workpiece processing tool 200 is to perform.

The first fan 210 is in closer proximity to the second end 109 (i.e., the bottom end) of the workpiece processing tool 200 than the first end 107 (i.e., the top end) of the workpiece processing tool 200. The first fan 210 is positioned in closer proximity to the second end 109 instead of the first end 107 to further facilitate or increase the airflow in the airflow direction as represented by the arrows 148 in the first region 114.

The second fan 212 is in closer proximity to the second end 109 (i.e., the bottom end) of the workpiece processing tool 200 than the first end 107 (i.e., the top end) of the workpiece processing tool 200. The second fan 212 is positioned in closer proximity to the second end 109 instead of the first end 107 to further facilitate or increase the airflow in the airflow direction as represented by the arrows 162 in the second region 116.

The third fan 214 is in closer proximity to the second end 109 (i.e., the bottom end) of the workpiece processing tool 200 than the first end 107 (i.e., the top end) of the workpiece processing tool 200. The third fan 214 is positioned in closer proximity to the second end 109 instead of the first end 107 to further facilitate or increase the airflow in the airflow direction as represented by the arrows 178 in the third region 118.

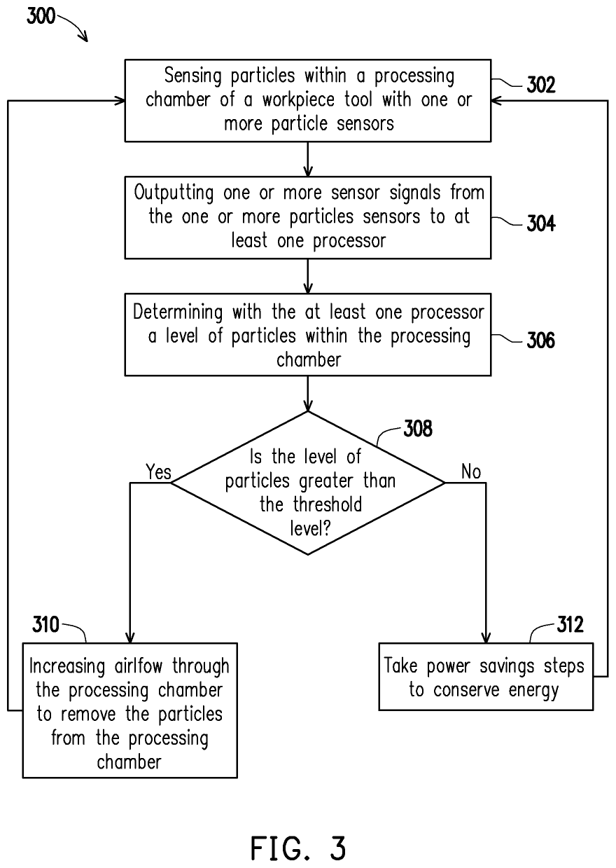

FIG. 3 is a flowchart 300 of a method of operating the first, second, and third air systems 120, 122, 124 of the process block 202 as shown in FIG. 2A, in accordance with some embodiments. The flowchart 300 includes a first step 302, a second step 304, a third step 306, a fourth step 308, a fifth step 310, and a sixth step 312.

In the first step 302, the one or more first particle sensors 204, the one or more second particle sensors 206, and the one or more third particle sensors 208 continuously and in real time monitor a level of particles or pollutants within the first region 114, the second region 116, and the third region 118, respectively. For example, in at least one embodiment, the one or more first, second, and third particle detectors 204, 206, 208 are electrical particle or pollutant sensors that utilize a voltage or current to detect the level of particles or pollutants within the first, second, and third regions 114, 116, 118, respectively.

In the second step 304, the one or more first, second, and third particle sensors 204, 206, 208 send one or more electrical signals to the processor 132 representative of the level of particles or pollutants within the first, second, and third regions 114, 116, 118, respectively. The processor 132 receives these one or more electrical signals from the one or more first, second, and third particle sensors 204, 206, 208.

In the third step 306, the processor 132 processes the one or more electrical signals received from the one or more first, second, and third particle sensors 204, 206, 208. For example, the processor 132 processes these one or more electrical signals to determine a first level of particles or pollutants in the first region 114, a second level of particles or pollutants within the second region 116, and a third level of particles or pollutants within the third region 118.

In a fourth step 308, after the processor 132 has received the one or more electrical signals in the second step 304 and has processed the one or more electrical signals in the third step 306, the processor 132 compares the first, second, and third levels of particles or pollutants to one or more selected thresholds. For example, the first level of particles or pollutants within the first region 114 as determined by the processor 132 is compared to a first selected threshold by the processor 132, the second level of particles or pollutants within the second region 116 as determined by the processor 132 is compared to a second selected threshold by the processor 132, and the third level of particles or pollutants within the third region 118 as determined by the processor 132 is compared to a third selected threshold by the processor 132.

In some embodiments, all of or at least some of the first, second, and third selected thresholds are different from each other. For example, when all of the first, second, and third selected thresholds are different from each other, the allowable amount of particles or pollutants within the first, second, and third regions 114, 116, 118 is different from each other. The first, second, and third selected thresholds may be different from each other depending on the process or technique that is being carried out within the first, second, and third regions 114, 116, 118 to prevent or reduce the likelihood of generating defects within one or more workpieces while balancing power and energy conservation efforts against the prevention or likelihood of generating defects within one or more workpieces with the process block 202. In some embodiments, all of the first, second, and third selected thresholds are the same as each other.

When at least one of the first, second, or third levels of particles or pollutants is greater than a corresponding one of the first, second, and third selected thresholds, respectively, the processor 132 proceeds to the fifth step 310. In the fifth step 310, the processor 132 sends output signals to at least one of, some of, or all of the first fan 210, the second fan 212, the third fan 214, and the one or more airflow dampers 126. For example and discussion purposes, when all of the first, second, and third levels of particles or pollutants are all greater than the first, second, and third selected thresholds, respectively, the processor 132 sends respective output signals to the first, second, and third fans 210, 212, 214 and all of the one or more airflow dampers 126. The respective output signals sent to the first, second, and third fans 210, 212, 214 results in the speed of the first, second, and third fans 210, 212, 214 increasing or being activated if previously not activated to increase the airflow in the airflow direction within the first, second, and third regions 114, 116, 118 as represented by the respective arrows 148, 162, 178.

Similarly, the respective output signals sent to the one or more airflow dampers 126 moves the airflow dampers away from a fully closed position towards a fully opened position increasing airflow into the one or more fluid passageways 128. This increase in the airflow through the one or more fluid passageways 128 results in increased airflow through and ejected by the first, second, and third airflow systems or assemblies 120, 122, 124. Increasing the airflow ejected from the first, second, and third airflow systems or assemblies 120, 122, 124 increases the airflow in the airflow direction within the first, second, and third regions 114, 116, 118 as represented by respective arrows 148, 162, 178.

By increasing the airflow in the airflow direction as represented by the respective arrows 148, 162, 178, the amounts of particles or pollutants within the first, second, and third regions are more readily and rapidly removed from the first, second, and third regions 114, 116, 118 of the process block 202. By removing and reducing the particles or pollutants within the first, second, and third regions 114, 116, 118, the first, second, and third levels of particles or pollutants are reduced within the first, second, and third regions 114, 116, 118, respectively. While this removal or reduction of the particles or pollutants is occurring, the one or more first, second, and third particle sensors 204, 206, 208 and the processor 132 continue to monitor, measure, and determine whether the levels of particles or pollutants within the first, second, and third regions 114, 116, 118 are greater than the first, second, and third selected thresholds.

In view of the improved and increased speed of removing the particles and pollutants when the particles are at a level greater than the selected threshold, a period of time between when the workpiece processing tool 200 needs to be brought offline for a cleaning operation to be performed is increased. This increase in the period of time between successive cleaning operations increases an operation time of the workpiece processing tool 200. This increase in the operation time of the workpiece processing tool 200 allows for a yield number of electronic devices or components being manufactured within the FAB (i.e., semiconductor manufacturing or fabrication plant) to be increased.

When none of the first, second, or third levels of particles or pollutants is greater than a corresponding one of the first, second, and third selected thresholds, respectively, the processor 132 proceeds to the sixth step 312. In the sixth step 312, the processor 132 sends output signals to at least one of, some of, or all of the first fan 210, the second fan 212, the third fan 214, and the one or more airflow dampers 126. For example and discussion purposes, when all of the first, second, and third levels of particles or pollutants are all less than the first, second, and third selected thresholds, respectively, the processor 132 sends respective output signals to the first, second, and third fans 210, 212, 214 and all of the one or more airflow dampers 126.

The respective output signals sent to the first, second, and third fans 210, 212, 214 results in the speed of the first, second, and third fans 210, 212, 214 decreasing or results in deactivation of the first, second, and third fans 210, 212, 214 to reduce the airflow in the airflow direction within the first, second, and third regions 114, 116, 118 as represented by the respective arrows 148, 162, 178. By reducing the speed of the first, second, and third fans 210, 212, 214 or deactivating the first, second, and third fans 210, 212, 214 once the first, second, and third levels of particles or pollutants within the first, second, and third regions 114, 116, 118 are determined to be below the first, second, and third selected thresholds, power is conserved avoiding continuously running the first, second, and third fans 210, 212, 214.

Similarly, the respective output signals sent to respective ones of the one or more airflow dampers 126 results in the respective ones of the one or more airflow dampers 126 moving away from a fully opened position towards a fully closed position reducing airflow through the first, second, and third airflow systems or assemblies 120, 122, 124. By reducing the airflow through the first, second, and third airflow systems or assemblies 120, 122, 124, an amount of air introduced into the first, second, and third regions 114, 116, 118 uses less of the air from the source of air 130 reducing operation costs of the workpiece processing tool 200 when the first, second, and third levels of particles or pollutants, respectively, are less than the first, second, and third selected thresholds, respectively.

While the above discussion discusses all of the first, second, and third levels of particles or pollutants being all greater than or less than the first, second, and third selected threshold, it will be readily appreciated that only some of or only one of the first, second, and third levels of particles or pollutants may be greater than or less than the first, second, and third selected thresholds. In view of this, the processor 132 during the flowchart 300 of the method of operation is configured to, in operation, activate various combinations of the first, second, and third fans 210, 212, 214, and control various combinations of the one or more airflow dampers 126 to manage the first, second, and third levels of particles or pollutants within the first, second, and third regions 114, 116, 118, respectively. As the processor 132 controls the first, second, and third fans 210, 212, 214 separately and dependent of each other, the first, second, and third levels of particles or pollutants within the first, second, and third regions 114, 116, 118 can be managed while conserving energy and power when only one or some of the first, second, and third fans 210, 212, 214 need to be activated to reduce the particles or pollutants only within some or one of the first, second, and third regions 114, 116, 118. Similarly, as the processor 132 controls the respective airflow dampers of the one or more airflow dampers 126 separately and dependent of each other, the first, second, and third levels of particles and pollutants within the first, second, and third regions 114, 116, 118 can be managed while conserving the amount of air provided from the source of air 130 to the first, second, and third airflow systems or assemblies 120, 122, 124 to reduce operating costs.

In some embodiments, when the first, second, and third levels of particles or pollutants are equal to the first, second, and third selected thresholds, the processor 132 outputs signals to one or more of the first, second, and third fans 210, 212, 214 and to one or more of the one or more airflow dampers 126 to control the various operational characteristics as discussed earlier herein.

In view of the discussion herein, the present disclosure is directed to providing one or more embodiments of a workpiece processing tool that contains one or more pluralities of particle or pollutant sensors that are in electrical communication with a processor. The processor collects signals from the one or more pluralities of particle sensors and determines whether respective levels of particles or pollutants are within one or more regions within a processing chamber of a process block of the workpiece processing tool. When the respective levels of particles or pollutants are greater than one or more selected thresholds, the processor outputs signals to one or more of a first fan, a second fan, and a third fan, and to one or more airflow dampers that provide air to one or more airflow systems or assemblies within the processing chamber of the process block.

At least one embodiment of a system of the present disclosure of a system is summarized as including: a workpiece processing tool including: a processing housing including: a top end; a bottom end opposite to the top end; at least one sidewall that extends from the bottom end to the top end; a processing chamber delimited by the top end, the bottom end, and the at least one sidewall, the processing chamber configured to, in operation, receive one or more workpieces that are to be processed within the processing chamber; an airflow assembly within the processing chamber of the processing housing, the airflow assembly including: one or more vertical airflow structures; one or more horizontal airflow structures that are at a non-zero angle to the one or more vertical airflow structures; one or more airflow pathways defined by the one or more vertical airflow structures and the one or more horizontal airflow structures; one or more particle sensors within the processing chamber, the one or more particle sensors configured to, in operation, detect particles within the processing chamber; a source of air; one or more airflow dampers in fluid communication with the source of air; and one or more airflow passageways including first ends in fluid communication with the one or more airflow dampers and second ends in fluid communication with the one or more vertical airflow structures.

At least one embodiment of a system of the present disclosure is summarized as including: a workpiece processing tool including: a first processing region to perform a first process; a second processing region to perform a second process; a first airflow assembly within the first processing region; a second airflow assembly within the second processing region; a source of air; a plurality of airflow dampers in fluid communication with the source of air; a plurality of fluid passageways in fluid communication with the plurality of airflow dampers, the plurality of fluid passageways including: at least one first fluid passageway in fluid communication with the first airflow assembly; and at least one second fluid passageway in fluid communication with the second airflow assembly; a plurality of first particle sensors in the first processing region; and a plurality of second particle sensors in the second processing region.

At least one embodiment of a method of the present disclosure is summarized as including: sensing particles within a processing chamber of a workpiece processing tool with one or more particle sensors within the processing chamber of the workpiece processing tool; outputting one or more sensor signals from the one or more particle sensors to at least one processor; determining with the at least one processor a level of particles within the processing chamber; comparing with the at least one processor the level of particles within the processing chamber to a threshold level; and when the level of particles is greater than the threshold level, expelling the particles from the processing chamber by moving one or more airflow dampers away from a fully closed position towards a fully opened position in fluid communication with a source of air increasing airflow through one or more fluid passageways in fluid communication with the one or more airflow dampers, increasing airflow into and through a first airflow assembly within the processing chamber and in fluid communication with the one or more fluid passageways, and increasing airflow ejected from one or more airflow outlets of the first airflow assembly and into the processing chamber.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A system comprising:
a workpiece processing tool including:
a processing chamber configured to, in operation, receive one or more workpieces;
an airflow assembly within the processing chamber, the airflow assembly including one or more airflow outlets configured to, in operation, eject air into the processing chamber;
one or more particle sensors within the processing chamber, the one or more particle sensors configured to, in operation, detect particles within the processing chamber and to output one or more sensor signals representative of a level of particles within the processing chamber;
a source of air;
one or more airflow dampers coupled between the source of air and the airflow assembly, the one or more airflow dampers movable between a closed position and an open position to regulate airflow from the source of air to the airflow assembly; and
at least one processor in electrical communication with the one or more particle sensors and the one or more airflow dampers, the at least one processor configured to, in operation:
receive the one or more sensor signals from the one or more particle sensors;
determine the level of particles within the processing chamber based at least in part on the one or more sensor signals;
compare the level of particles to a threshold level; and
output one or more control signals to the one or more airflow dampers based at least in part on the comparison of the level of particles to the threshold level.

2. The system of claim 1, wherein, when the level of particles is greater than the threshold level, the at least one processor is configured to, in operation, output the one or more control signals to move the one or more airflow dampers away from the closed position towards the open position to increase airflow through the airflow assembly and into the processing chamber.

3. The system of claim 2, wherein, when the level of particles is less than the threshold level, the at least one processor is configured to, in operation, output the one or more control signals to move the one or more airflow dampers away from the open position towards the closed position to reduce airflow through the airflow assembly.

4. The system of claim 1, further comprising a fan coupled proximate to a bottom end of the processing chamber, the fan in electrical communication with the at least one processor, the at least one processor further configured to, in operation, output one or more fan control signals to the fan based at least in part on the comparison of the level of particles to the threshold level.

5. The system of claim 4, wherein, when the level of particles is greater than the threshold level, the at least one processor is configured to increase power to the fan to direct a flow of air through the processing chamber in an airflow direction from a top end of the processing chamber towards the bottom end of the processing chamber.

6. The system of claim 4, wherein, when the level of particles is less than the threshold level, the at least one processor is configured to, in operation, reduce power to the fan to conserve energy.

7. The system of claim 1, wherein the airflow assembly further comprises one or more vertical airflow structures and one or more horizontal airflow structures coupled to the one or more vertical airflow structures, the one or more airflow outlets disposed on the one or more horizontal airflow structures, and the one or more airflow outlets directed in an airflow direction from a top end of the processing chamber towards a bottom end of the processing chamber.

8. The system of claim 1, further comprising one or more fluid passageways including first ends coupled to the one or more airflow dampers and second ends coupled to the airflow assembly, the one or more fluid passageways configured to, in operation, convey air from the one or more airflow dampers to the airflow assembly.

9. The system of claim 1, wherein the one or more particle sensors are configured to, in operation, continuously monitor the level of particles within the processing chamber in real time.

10. A system comprising:
a workpiece processing tool including:
a first processing region configured to perform a first process on one or more workpieces;
a second processing region configured to perform a second process on the one or more workpieces;
a first airflow assembly within the first processing region, the first airflow assembly including one or more first airflow outlets configured to, in operation, eject air into the first processing region;
a second airflow assembly within the second processing region, the second airflow assembly including one or more second airflow outlets configured to, in operation, eject air into the second processing region;
a plurality of first particle sensors within the first processing region;
a plurality of second particle sensors within the second processing region;
a source of air;
a plurality of airflow dampers coupled between the source of air and the first airflow assembly and the second airflow assembly;
a first fan coupled proximate to a bottom end of the first processing region;
a second fan coupled proximate to a bottom end of the second processing region; and
at least one processor in electrical communication with the plurality of first particle sensors, the plurality of second particle sensors, the plurality of airflow dampers, the first fan, and the second fan, the at least one processor configured to, in operation:
determine a first level of particles within the first processing region based at least in part on sensor signals received from the plurality of first particle sensors;
determine a second level of particles within the second processing region based at least in part on sensor signals received from the plurality of second particle sensors;
compare the first level of particles to a first threshold level and the second level of particles to a second threshold level; and
independently control the plurality of airflow dampers and the first fan and the second fan based at least in part on the comparisons.

11. The system of claim 10, wherein, when the first level of particles is greater than the first threshold level, the at least one processor is configured to, in operation, increase airflow through the first airflow assembly by adjusting a corresponding one of the plurality of airflow dampers and to increase power to the first fan.

12. The system of claim 10, wherein, when the first level of particles is less than the first threshold level and the second level of particles is less than the second threshold level, the at least one processor is configured to, in operation, reduce power to the first fan and the second fan to conserve energy.

13. The system of claim 10, further comprising:
a third processing region configured to, in operation, perform a third process on the one or more workpieces;
a third airflow assembly within the third processing region;
a plurality of third particle sensors within the third processing region; and
a third fan coupled proximate to a bottom end of the third processing region, wherein the at least one processor is further in electrical communication with the plurality of third particle sensors and the third fan.

14. The system of claim 13, wherein the first process, the second process, and the third process are different stages of a photolithography process.

15. The system of claim 10, wherein the first threshold level and the second threshold level are different from each other.

16. A method comprising:
detecting, with a plurality of particle sensors within a processing chamber of a workpiece processing tool, particles within the processing chamber;
transmitting sensor signals from the plurality of particle sensors to at least one processor;
determining, with the at least one processor, a level of particles within the processing chamber based at least in part on the sensor signals;
comparing, with the at least one processor, the level of particles to a threshold level;
when the level of particles is greater than the threshold level, increasing airflow through the processing chamber by adjusting one or more airflow dampers coupled between a source of air and an airflow assembly within the processing chamber to move the one or more airflow dampers away from a closed position towards an open position, and increasing power to a fan coupled proximate to a bottom end of the processing chamber to direct a flow of air through the processing chamber in an airflow direction from a top end of the processing chamber towards the bottom end of the processing chamber; and
when the level of particles is less than the threshold level, reducing airflow through the processing chamber by adjusting the one or more airflow dampers towards the closed position and reducing power to the fan.

17. The method of claim 16, wherein increasing airflow through the processing chamber includes increasing airflow ejected from one or more airflow outlets of the airflow assembly into the processing chamber, the one or more airflow outlets directed in the airflow direction from the top end of the processing chamber towards the bottom end of the processing chamber.

18. The method of claim 16, wherein detecting particles with the plurality of particle sensors includes continuously monitoring the level of particles within the processing chamber in real time.

19. The method of claim 16, wherein the airflow assembly includes one or more vertical airflow structures and one or more horizontal airflow structures coupled to the one or more vertical airflow structures, and wherein increasing airflow through the processing chamber includes increasing airflow through the one or more vertical airflow structures and the one or more horizontal airflow structures.

20. The method of claim 16, wherein the fan is positioned in closer proximity to the bottom end of the processing chamber than to the top end of the processing chamber.
